(19) United States
(12) Patent Application Publication
(10) Pub. No.: US 2017/0036911 A1
(43) Pub. Date: Feb. 9, 2017

(54) PERFORATED SHEETS OF GRAPHENE-BASED MATERIAL

(71) Applicant: Lockheed Martin Corporation, Bethesda, MD (US)

(72) Inventors: Jacob L. SWETT, Redwood City, CA (US); Peter V. BEDWORTH, Los Gatos, CA (US); Scott E. HEISE, San Jose, CA (US); Steven W. SINTON, Palo Alto, CA (US); Sarah M. SIMON, Baltimore, MD (US)

(73) Assignee: Lockheed Martin Corporation, Bethesda, MD (US)

(21) Appl. No.: 15/099,239

(22) Filed: Apr. 14, 2016

Related U.S. Application Data
(60) Provisional application No. 62/201,539, filed on Aug. 5, 2015.
(60) Provisional application No. 62/201,527, filed on Aug. 5, 2015.

(51) Int. Cl. C01B 31/00; C23C 16/44; C01B 31/02; C23C 16/26

(52) U.S. Cl. CPC C01B 31/00; C23C 16/26; C23C 16/44; C01B 31/0213

(57) ABSTRACT

Perforated sheets of graphene-based material having a plurality of perforations are provided. The perforated sheets may include perforated single layer graphene. The perforations may be located over greater than 10% of said area of said sheet of graphene-based material and the mean pore size of the perforations selected from the range of 0.3 nm to 1 μm. Methods for making the perforated sheets are also provided.

### CROSS REFERENCE TO RELATED APPLICATIONS

The present application claims the benefit of priority to U.S. Provisional Application No. 62/201,527, entitled “Perforated Sheets of Graphene-based Material,” filed on Aug. 5, 2015, and U.S. Provisional Application No. 62/201,539, entitled “Perforatable Sheets of Graphene-based Material,” filed Aug. 5, 2015, both of the contents of which are incorporated herein by reference in their entirety. Contemporaneously with this application, another U.S. Patent Application claiming the benefit of priority to the same two provisional applications is being filed as Ser. No. ______, entitled “Perforatable Sheets of Graphene-Based Material,” the contents of which are incorporated herein by reference in their entirety.

### BACKGROUND

In its various forms, graphene has garnered widespread interest for use in a number of applications, primarily due to its favorable combination of high electrical and thermal conductivity values, excellent in-plane mechanical strength, and unique optical and electronic properties. Perforated graphene has been suggested for use in filtering applications.

Formation of apertures or perforations in graphene by exposure to oxygen (O₂) has been described in Liu et al, Nano Lett. 2008, Vol. 8, no. 7, pp. 1965-1970. As described therein, through apertures or holes in the 20 to 180 nm range were etched in single layer graphene using 350 Torr of oxygen in 1 atmosphere (atm) Argon at 500° C. for 2 hours. The graphene samples were reported to have been prepared by mechanical exfoliation of Kish graphite.

Another method is described in Kim et al. “Fabrication and Characterization of Large Area, Semiconducting Nanoperforated Graphene Materials,” Nano Letters 2010 Vol. 10, No. 4, Mar. 1, 2010, pp 1125-1131 . This reference describes use of a self-assembling polymer that creates a mask suitable for patterning using reactive ion etching (RIE). A P(S-blockMMA) block copolymer forms an array of PMMA columns that form vias for the RIE upon removal. It was reported that the graphene was formed by mechanical exfoliation.

### BRIEF SUMMARY

Some embodiments provide a sheet comprising a perforated sheet of graphene-based material. The perforations may be located over greater than 10% or greater than 15% of the area of said sheet of graphene-based material. In some additional examples, the perforated area may correspond to 0.1% or greater of said area of said sheet of graphene-based material. In further embodiments, the mean pore size of the perforations may be selected from the range of 0.3 nm to 1 μm. At least one lateral dimension of the sheet may be greater than 1 mm, greater than 1 cm, or greater than 3 cm.

Some embodiments provide a perforated sheet of graphene-based material, the graphene-based material comprising single layer graphene prior to perforation, the perforated sheet of graphene-based material comprising a plurality of perforations characterized in that the perforations may be located over greater than 10% of said area of said sheet of graphene-based material and the mean pore size of the perforations may be selected from the range of 0.3 nm to 1 μm. In some embodiments, the perforated sheet of graphene-based material comprises perforated single layer graphene having a plurality of perforations characterized in that the perforations may be located over greater than 10% of said area of said sheet of graphene-based material and the mean pore size of the perforations may be selected from the range of 0.3 nm to 1 μm

In some embodiments, the coefficient of variation of the pore size may be 0.1 to 2, 0.5 to 2 or 0.1 to 0.5. In some further embodiments, the mean pore size of the perforations may be from 0.3 nm to 0.1 μm or 0.3 nm to 1 μm.

In some embodiments, the sheet of graphene-based material prior to perforation comprises a single layer of graphene having a surface and a non-graphenic carbon-based material provided on said single layer graphene. In some embodiments, the single layer graphene may have at least two surfaces, such as a substrate side surface and a free surface forming opposed surfaces. For example, the non-graphenic carbon-based material may be provided on one or two of the surfaces of the single layer graphene. In some embodiments, the sheet of graphene-based material comprises a sheet of single or multilayer graphene or a combination thereof.

In some embodiments, the sheet of graphene-based material may be formed by chemical vapor deposition (CVD) followed by at least one additional conditioning or treatment step prior to perforation. In some embodiments, the conditioning methods described herein may reduce the extent to which the non-graphenic carbon based material covers the surface of the single layer graphene, may reduce the mobility of said non-graphenic carbon based material, and may reduce the volatility of said non-graphenic carbon based material and/or combinations thereof.

In some embodiments, the non-graphenic carbon-based material comprises at least 80% carbon or 20% to 100% carbon. In some further embodiments, said non-graphenic carbon-based material further comprises non-carbon elements. In some embodiments, said non-carbon elements may be selected from the group consisting of hydrogen, oxygen, silicon, copper, iron and combinations thereof. In some embodiments, said non-graphenic carbon-based material has an elemental composition comprising carbon, hydrogen and oxygen. In further embodiments, said non-graphenic carbon-based material may have a molecular composition comprising amorphous carbon, one or more hydrocarbons or any combination of these. In some further embodiments, a non-carbon element, such as boron or silicon may substitute for carbon in the lattice. In some embodiments, said non-graphenic carbon-based material may not exhibit long range order. In some embodiments, the non-graphenic carbon-based material may be in physical contact with said surface(s) of said single layer graphene. In some embodiments, the characteristics of the non-graphenic carbon material are those as determined after perforation.

Following perforation, the perforated sheet of graphene-based material may retain single layer graphene or the single layer graphene present before perforation may become substantially disordered. In some embodiments, said single layer graphene may be characterized by an average size domain for long range order greater than or equal to 1 micrometer (1 μm). In some further embodiments, said single layer graphene may have an extent of disorder characterized by long range lattice periodicity on the order of 1 micrometer. In some additional embodiments, said single layer graphene has an extent of disorder characterized by less than 1% content of lattice defects. In some embodiments, the crystal lattice of the single layer graphene may be disrupted over the scale of 1 nm to 10 nm. In some additional embodiments, the perforated sheet of graphene-based material may not exhibit long range order. In some embodiments, disorder in the perforated sheet of graphene-based material may be characterized by the absence of the 6 characteristic diffraction spots of graphene which characterize the reciprocal lattice space of ordered graphene.

In some embodiments, methods for making perforated sheets of graphene based material are provided. For example, some embodiments provide a method for perforating a sheet of graphene-based material, said method comprising: providing said sheet of graphene-based material comprising a single layer graphene having a surface; and a non-graphenic carbon-based material provided on said single layer graphene; wherein greater than 10% and less than 80% of said surface of said single layer graphene may be covered by said non-graphenic carbon-based material; and exposing the sheet of graphene-based material to ions characterized by an ion energy ranging from 5 eV to 100 keV and an fluence ranging from 1×10¹³ ions/cm² to 1×10²¹ ions/cm². In some embodiments, the single layer graphene comprises at least two surfaces and greater than 10% and less than 80% of said surfaces of said single layer graphene may be covered by said non-graphenic carbon-based material. In some further embodiments, at least a portion of the single layer graphene may be suspended. In some embodiments, a mask or template may not be present between the source of ions and the sheet of graphene-based material. In some embodiments, the source of ions may be an ion source that is collimated, such as a broad beam or flood source. In some embodiments, the ions are noble gas ions, are selected from the group consisting of Xe+ ions, Ne+ ions, or Ar+ ions, or are helium ions.

In some embodiments, the ions are selected from the group consisting of Xe+ ions, Ne+ ions, and Ar+ ions, the ion energy ranges from 5 eV to 50 eV and the ion dose ranges from 5×10¹⁴ ions/cm² to 5×10¹⁵ ions/cm². In some embodiments, the ion energy ranges from 1 keV to 40 keV and the ion dose ranges from 1×10¹⁹ ions/cm² to 1×10²¹ ions/cm². These parameters may be used for He ions. In some further embodiments, a background gas may be present during ion irradiation. For example, the sheet of graphene-based material may be exposed to the ions in an environment comprising partial pressure of 5×10⁻⁴ torr to 5×10⁻⁵ torr of oxygen, nitrogen or carbon dioxide at a total pressure of 10⁻³ torr to 10⁻⁵ torr. In some embodiments, the ion irradiation conditions when a background gas is present include an ion energy ranging from 100 eV to 1000 eV and an ion dose ranging from 1×10¹³ ions/cm² to 1×10¹⁴ ions/cm². A quasi-neutral plasma may be used under these conditions.

In some embodiments, a method for perforating a sheet of graphene-based material is provided, said method comprising: providing said sheet of graphene-based material comprising a single layer graphene having a surface; and a non-graphenic carbon-based material provided on said single layer graphene; wherein greater than 10% and less than 80% of said surface of said single layer graphene is covered by said non-graphenic carbon-based material; and exposing said sheet of graphene-based material to ultraviolet radiation and an oxygen containing gas at an irradiation intensity from 10 to 100 mW/cm² for a time from 60 to 1200 sec. In some embodiments, the single layer graphene comprises at least two surfaces and greater than 10% and less than 80% of said surfaces of said single layer graphene is covered by said non-graphenic carbon-based material. In some embodiments, at least a portion of the single layer graphene is suspended. In some embodiments, a mask or template is not present between the source of ions and the sheet of graphene-based material.

### BRIEF DESCRIPTION OF THE DRAWINGS

FIGS. 1A and 1B are transmission electron microscope (TEM) images illustrating a portion of a sheet of graphene based material after perforation using UV-oxygen treatment.

FIGS. 2A and 2B are TEM images illustrating a portion of a sheet of graphene based material after perforation using Xe⁺ ions.

FIG. 3 and FIG. 4 are TEM images illustrating graphene based material after perforation using Ne⁺ ions.

FIG. 5 and FIG. 6 are TEM images illustrating graphene based material after perforation using He⁺ ions.

### DETAILED DESCRIPTION

Graphene represents a form of carbon in which the carbon atoms reside within a single atomically thin sheet or a few layered sheets (e.g., about 20 or less) of fused six-membered rings forming an extended sp²-hybridized carbon planar lattice. Graphene-based materials include, but are not limited to, single layer graphene, multilayer graphene or interconnected single or multilayer graphene domains and combinations thereof. In some embodiments, graphene-based materials also include materials which have been formed by stacking single or multilayer graphene sheets. In some embodiments, multilayer graphene includes 2 to 20 layers, 2 to 10 layers or 2 to 5 layers. In some embodiments, layers of multilayered graphene are stacked, but are less ordered in the z direction (perpendicular to the basal plane) than a thin graphite crystal.

In some embodiments, a sheet of graphene-based material may be a sheet of single or multilayer graphene or a sheet comprising a plurality of interconnected single or multilayer graphene domains, which may be observed in any known manner such as using for example small angle electron diffraction, transmission electron microscopy, etc. In some embodiments, the multilayer graphene domains have 2 to 5 layers or 2 to 10 layers. As used herein, a domain refers to a region of a material where atoms are substantially uniformly ordered into a crystal lattice. A domain is uniform within its boundaries, but may be different from a neighboring region. For example, a single crystalline material has a single domain of ordered atoms. In some embodiments, at least some of the graphene domains are nanocrystals, having domain size from 1 to 100 nm or 10-100 nm. In some embodiments, at least some of the graphene domains have a domain size greater than 100 nm to 1 micron, or from 200 nm to 800 nm, or from 300 nm to 500 nm. In some embodiments, a domain of multilayer graphene may overlap a neighboring domain. Grain boundaries formed by crystallographic defects at edges of each domain may differentiate between neighboring crystal lattices. In some embodiments, a first crystal lattice may be rotated relative to a second crystal lattice, by rotation about an axis perpendicular to the plane of a sheet, such that the two lattices differ in crystal lattice orientation.

In some embodiments, the sheet of graphene-based material is a sheet of single or multilayer graphene or a combination thereof. In some other embodiments, the sheet of graphene-based material is a sheet comprising a plurality of interconnected single or multilayer graphene domains. In some embodiments, the interconnected domains are covalently bonded together to form the sheet. When the domains in a sheet differ in crystal lattice orientation, the sheet is polycrystalline.

In some embodiments, the thickness of the sheet of graphene-based material is from 0.3 to 10 nm, 0.34 to 10 nm, from 0.34 to 5 nm, or from 0.34 to 3 nm. In some embodiments, the thickness includes both single layer graphene and the non-graphenic carbon.

In some embodiments, a sheet of graphene-based material comprises intrinsic or native defects. Intrinsic or native defects may result from preparation of the graphene-based material in contrast to perforations which are selectively introduced into a sheet of graphene-based material or a sheet of graphene. Such intrinsic or native defects may include, but are not limited to, lattice anomalies, pores, tears, cracks or wrinkles. Lattice anomalies can include, but are not limited to, carbon rings with other than 6 members (e.g. 5, 7 or 9 membered rings), vacancies, interstitial defects (including incorporation of non-carbon atoms in the lattice), and grain boundaries. Perforations are distinct from openings in the graphene lattice due to intrinsic or native defects or grain boundaries, but testing and characterization of the final membrane such as mean pore size and the like encompasses all openings regardless of origin since they are all present.

In some embodiments, graphene is the dominant material in a graphene-based material. For example, a graphene-based material may comprise at least 20% graphene, at least 30% graphene, or at least 40% graphene, or at least 50% graphene, or at least 60% graphene, or at least 70% graphene, or at least 80% graphene, or at least 90% graphene, or at least 95% graphene. In some embodiments, a graphene-based material comprises a range of graphene selected from 30% to 95%, or from 40% to 80% from 50% to 70%, from 60% to 95% or from 75% to 100%. The amount of graphene in the graphene-based material is measured as an atomic percentage utilizing known methods including transmission electron microscope examination, or alternatively if TEM is ineffective another similar measurement technique.

In some embodiments, a sheet of graphene-based material further comprises non-graphenic carbon-based material located on at least one surface of the sheet of graphene-based material. In some embodiments, the sheet is exemplified by two base surfaces (e.g. top and bottom faces of the sheet, opposing faces) and side faces (e.g. the side faces of the sheet). In some further embodiments, the “bottom” face of the sheet is that face which contacted the substrate during growth of the sheet and the “free” face of the sheet opposite the “bottom” face. In some embodiments, non-graphenic carbon-based material may be located on one or both base surfaces of the sheet (e.g. the substrate side of the sheet and/or the free surface of the sheet). In some further embodiments, the sheet of graphene-based material includes a small amount of one or more other materials on the surface, such as, but not limited to, one or more dust particles or similar contaminants.

In some embodiments, the amount of non-graphenic carbon-based material is less than the amount of graphene. In some further embodiments, the amount of non-graphenic carbon material is three to five times the amount of graphene; this is measured in terms of mass. In some additional embodiments, the non-graphenic carbon material is characterized by a percentage by mass of said graphene-based material selected from the range of 0% to 80%. In some embodiments, the surface coverage of the sheet of non-graphenic carbon-based material is greater than zero and less than 80%, from 5% to 80%, from 10% to 80%, from 5% to 50% or from 10% to 50%. This surface coverage may be measured with transmission electron microscopy, which gives a projection. In some embodiments, the amount of graphene in the graphene-based material is from 60% to 95% or from 75% to 100%. The amount of graphene in the graphene-based material is measured as a mass percentage utilizing known methods preferentially using transmission electron microscope examination, or alternatively if TEM is ineffective using other similar techniques.

In some embodiments, the non-graphenic carbon-based material does not possess long range order and is classified as amorphous. In some embodiments, the non-graphenic carbon-based material further comprises elements other than carbon and/or hydrocarbons. In some embodiments, non-carbon elements which may be incorporated in the non-graphenic carbon include hydrogen, oxygen, silicon, copper, and iron. In some further embodiments, the non-graphenic carbon-based material comprises hydrocarbons. In some embodiments, carbon is the dominant material in non-graphenic carbon-based material. For example, a non-graphenic carbon-based material in some embodiments comprises at least 30% carbon, or at least 40% carbon, or at least 50% carbon, or at least 60% carbon, or at least 70% carbon, or at least 80% carbon, or at least 90% carbon, or at least 95% carbon. In some embodiments, a non-graphenic carbon-based material comprises a range of carbon selected from 30% to 95%, or from 40% to 80%, or from 50% to 70%. The amount of carbon in the non-graphenic carbon-based material is measured as an atomic percentage utilizing known methods preferentially using transmission electron microscope examination, or alternatively if TEM is ineffective, using other similar techniques.

Perforation techniques suitable for use in perforating the graphene-based materials may include described herein ion-based perforation methods and UV-oxygen based methods.

Ion-based perforation methods include methods in which the graphene-based material is irradiated with a directional source of ions. In some further embodiments, the ion source is collimated. In some embodiments, the ion source is a broad beam or flood source. A broad field or flood ion source can provide an ion flux which is significantly reduced compared to a focused ion beam. The ion source inducing perforation of the graphene or other two-dimensional material is considered to provide a broad ion field, also commonly referred to as an ion flood source. In some embodiments, the ion flood source does not include focusing lenses. In some embodiments, the ion source is operated at less than atmospheric pressure, such as at 10⁻³ to 10⁻⁵ torr or 10⁻⁴ to 10⁻⁶ torr. In some embodiments, the environment also contains background amounts (e.g. on the order of 10⁻⁵ torr) of oxygen (O₂), nitrogen (N₂) or carbon dioxide (CO₂). In some embodiments, the ion beam may be perpendicular to the surface of the layer(s) of the material (incidence angle of 0 degrees) or the incidence angle may be from 0 to 45 degrees, 0 to 20 degrees, 0 to 15 degrees or 0 to 10 degrees. In some further embodiments, exposure to ions does not include exposure to plasma.

In some embodiments, UV-oxygen based perforation methods include methods in which the graphene-based material is simultaneously exposed to ultraviolet (UV) light and an oxygen containing gas Ozone may be generated by exposure of an oxygen containing gas such as oxygen or air to the UV light. Ozone may also be supplied by an ozone generator device. In some embodiments, the UV-oxygen based perforation method further includes exposure of the graphene-based material to atomic oxygen. Suitable wavelengths of UV light include, but are not limited to wavelengths below 300 nm or from 150 nm to 300 nm. In some embodiments, the intensity from 10 to 100 mW/cm² at 6 mm distance or 100 to 1000 mW/cm² at 6 mm distance. For example, suitable light is emitted by mercury discharge lamps (e.g. about 185 nm and 254 nm). In some embodiments, UV/oxygen cleaning is performed at room temperature or at a temperature greater than room temperature. In some further embodiments, UV/oxygen cleaning is performed at atmospheric pressure (e.g. 1 atm) or under vacuum.

Perforations are sized as described herein to provide desired selective permeability of a species (atom, molecule, protein, virus, cell, etc.) for a given application. Selective permeability relates to the propensity of a porous material or a perforated two-dimensional material to allow passage (or transport) of one or more species more readily or faster than other species. Selective permeability allows separation of species which exhibit different passage or transport rates. In two-dimensional materials selective permeability correlates to the dimension or size (e.g., diameter) of apertures and the relative effective size of the species. Selective permeability of the perforations in two-dimensional materials such as graphene-based materials can also depend on functionalization of perforations (if any) and the specific species. Separation or passage of two or more species in a mixture includes a change in the ratio(s) (weight or molar ratio) of the two or more species in the mixture during and after passage of the mixture through a perforated two-dimensional material.

In some embodiments, the characteristic size of the perforation is from 0.3 to 10 nm, from 1 to 10 nm, from 5 to 10 nm, from 5 to 20 nm, from 10 nm to 50 nm, from 50 nm to 100 nm, from 50 nm to 150 nm, from 100 nm to 200 nm, or from 100 nm to 500 nm. In some embodiments, the average pore size is within the specified range. In some embodiments, 70% to 99%, 80% to 99%, 85% to 99% or 90 to 99% of the perforations in a sheet or layer fall within a specified range, but other pores fall outside the specified range.

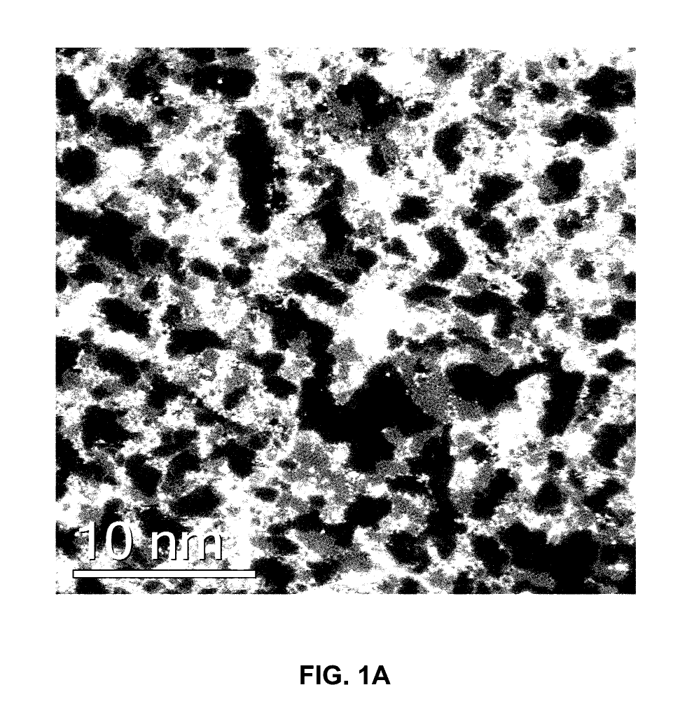

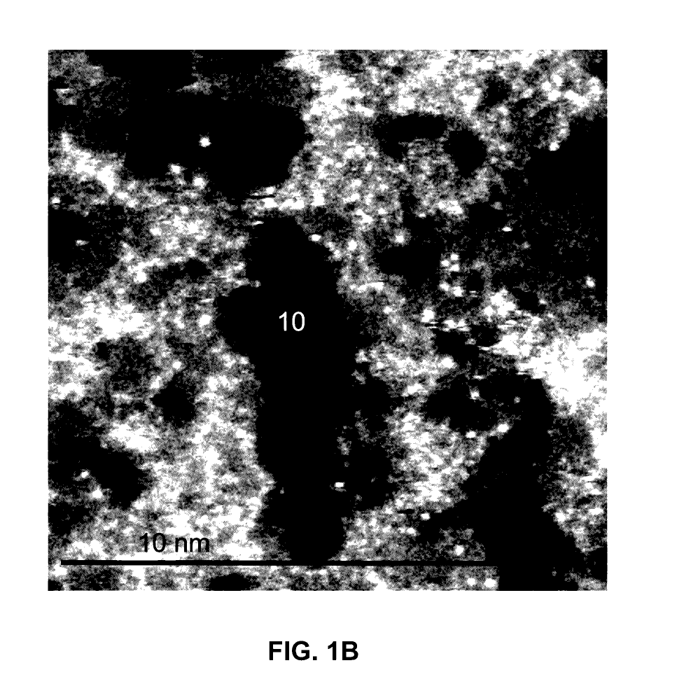

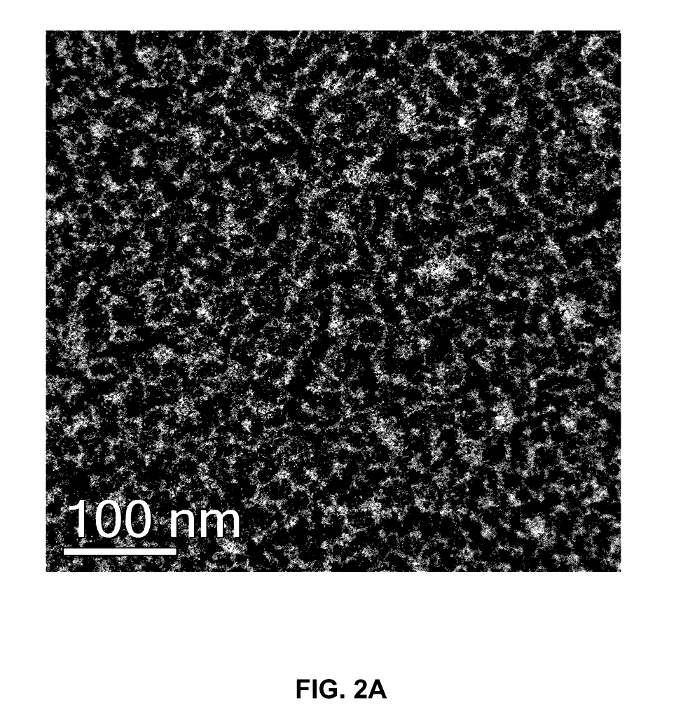

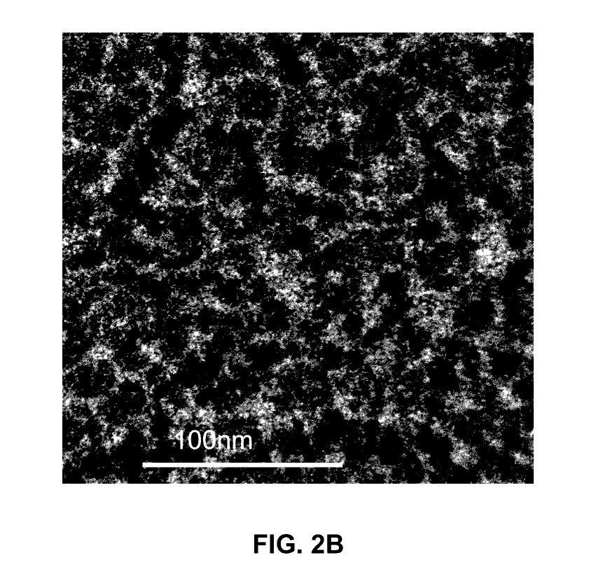

Nanomaterials in which pores are intentionally created may be referred to as perforated graphene, perforated graphene-based materials or perforated two-dimensional materials, and the like. Perforated graphene-based materials include materials in which non-carbon atoms have been incorporated at the edges of the pores. Pore features and other material features may be characterized in a variety of manners including in relation to size, area, domains, periodicity, coefficient of variation, etc. For instance, the size of a pore may be assessed through quantitative image analysis utilizing images preferentially obtained through transmission electron microscopy, and if TEM is ineffective, through scanning electron microscopy and the like, as for example presented in FIGS. 1 and 2. The boundary of the presence and absence of material identifies the contour of a pore. The size of a pore may be determined by shape fitting of an expected species against the imaged pore contour where the size measurement is characterized by smallest dimension unless otherwise specified. For example, in some instances, the shape may be round or oval. The round shape exhibits a constant and smallest dimension equal to its diameter. The width of an oval is its smallest dimension. The diameter and width measurements of the shape fitting in these instances provide the size measurement, unless specified otherwise.

Each pore size of a test sample may be measured to determine a distribution of pore sizes within the test sample. Other parameters may also be measured such as area, domain, periodicity, coefficient of variation, etc. Multiple test samples may be taken of a larger membrane to determine that the consistency of the results properly characterizes the whole membrane. In such instance, the results may be confirmed by testing the performance of the membrane with test species. For example, if measurements indicate that certain sizes of species should be restrained from transport across the membrane, a performance test provides verification with test species. Alternatively, the performance test may be utilized as an indicator that the pore measurements will determine a concordant pore size, area, domains, periodicity, coefficient of variation, etc.

The size distribution of holes may be narrow, e.g., limited to 0.1-0.5 coefficient of variation. In some embodiments, the characteristic dimension of the holes is selected for the application.

In some embodiments involving circular shape fitting the equivalent diameter of each pore is calculated from the equation A=πd²/4. Otherwise, the area is a function of the shape fitting. When the pore area is plotted as a function of equivalent pore diameter, a pore size distribution may be obtained. The coefficient of variation of the pore size may be calculated herein as the ratio of the standard deviation of the pore size to the mean of the pore size as measured across the test samples. The average area of perforations is an averaged measured area of pores as measured across the test samples.

In some embodiments, the ratio of the area of the perforations to the ratio of the area of the sheet may be used to characterize the sheet as a density of perforations. The area of a test sample may be taken as the planar area spanned by the test sample. Additional sheet surface area may be excluded due to wrinkles other non-planar features. Characterization may be based on the ratio of the area of the perforations to the test sample area as density of perforations excluding features such as surface debris. Characterization may be based on the ratio of the area of the perforations to the suspended area of the sheet. As with other testing, multiple test samples may be taken to confirm consistency across tests and verification may be obtained by performance testing. The density of perforations may be, for example, 2 per nm² (2/nm²to 1 per μm² (1/μm²).

In some embodiments, the perforated area comprises 0.1% or greater, 1% or greater or 5% or greater of the sheet area, less than 10% of the sheet area, less than 15% of the sheet area, from 0.1% to 15% of the sheet area, from 1% to 15% of the sheet area, from 5% to 15% of the sheet area or from 1% to 10% of the sheet area. In some further embodiments, the perforations are located over greater than 10% or greater than 15% of said area of said sheet of graphene-based material. A macroscale sheet is macroscopic and observable by the naked eye. In some embodiments, at least one lateral dimension of the sheet is greater than 3 cm, greater than 1 cm, greater than 1 mm or greater than 5 mm. In some further embodiments, the sheet is larger than a graphene flake which would be obtained by exfoliation of graphite in known processes used to make graphene flakes. For example, the sheet has a lateral dimension greater than about 1 micrometer. In an additional embodiment, the lateral dimension of the sheet is less than 10 cm. In some further embodiments, the sheet has a lateral dimension (e.g., perpendicular to the thickness of the sheet) from 10 nm to 10 cm or greater than 1 mm and less than 10 cm.

Chemical vapor deposition growth of graphene-based material typically involves use of a carbon containing precursor material, such as methane and a growth substrate. In some embodiments, the growth substrate is a metal growth substrate. In some embodiments, the metal growth substrate is a substantially continuous layer of metal rather than a grid or mesh. Metal growth substrates compatible with growth of graphene and graphene-based materials include transition metals and their alloys. In some embodiments, the metal growth substrate is copper based or nickel based. In some embodiments, the metal growth substrate is copper or nickel. In some embodiments, the graphene-based material is removed from the growth substrate by dissolution of the growth substrate.

In some embodiments, the sheet of graphene-based material is formed by chemical vapor deposition (CVD) followed by at least one additional conditioning or treatment step. In some embodiments, the conditioning step is selected from thermal treatment, UV-oxygen treatment, ion beam treatment, and combinations thereof In some embodiments, thermal treatment may include heating to a temperature from 200° C. to 800° C. at a pressure of 10⁻⁷ torr to atmospheric pressure for a time of 2 hours to 8 hours. In some embodiments, UV-oxygen treatment may involve exposure to light from 150 nm to 300 nm and an intensity from 10 to 100 mW/cm² at 6 mm distance for a time from 60 to 1200 seconds. In some embodiments, UV-oxygen treatment may be performed at room temperature or at a temperature greater than room temperature. In some further embodiments, UV-oxygen treatment may be performed at atmospheric pressure (e.g. 1 atm) or under vacuum. In some embodiments, ion beam treatment may involve exposure of the graphene-based material to ions having an ion energy from 50 eV to 1000 eV (for pretreatment) and the fluence is from 3×10¹⁰ ions/cm² to 8×10¹¹ ions/cm² or 3×10¹⁰ ions/cm² to 8×10¹³ ions/cm² (for pretreatment). In some further embodiments, the source of ions may be collimated, such as a broad beam or flood source. In some embodiments, the ions may be noble gas ions such as Xe⁺. In some embodiments, one or more conditioning steps are performed while the graphene-based material is attached to a substrate, such as a growth substrate.

In some embodiments, the conditioning treatment affects the mobility and/or volatility of the non-graphitic carbon-based material. In some embodiments, the surface mobility of the non-graphenic carbon-based material is such that when irradiated with perforation parameters such as described herein, the non-graphenic carbon-based material, may have a surface mobility such that the perforation process results ultimately in perforation. Without wishing to be bound by any particular belief, hole formation is believed to related to beam induced carbon removal from the graphene sheet and thermal replenishment of carbon in the hole region by non graphenic carbon. The replenishment process may be dependent upon energy entering the system during perforation and the resulting surface mobility of the non-graphenic carbon based material. To form holes, the rate of graphene removal may be higher than the non-graphenic carbon hole filling rate. These competing rates depend on the non-graphenic carbon flux (e.g., mobility [viscosity and temperature] and quantity) and the graphene removal rate (e.g., particle mass, energy, flux).

In some embodiments, the volatility of the non-graphenic carbon-based material may be less than that which is obtained by heating the sheet of graphene-based material to 500° C. for 4 hours in vacuum or at atmospheric pressure with an inert gas.

In various embodiments, CVD graphene or graphene-based material can be liberated from its growth substrate (e.g., Cu) and transferred to a supporting grid, mesh or other supporting structure. In some embodiments, the supporting structure may be configured so that at least some portions of the sheet of graphene-based material are suspended from the supporting structure. For example, at least some portions of the sheet of graphene-based material may not be in contact with the supporting structure.

In some embodiments, the sheet of graphene-based material following chemical vapor deposition comprises a single layer of graphene having at least two surfaces and non-graphenic carbon based material may be provided on said surfaces of the single layer graphene. In some embodiments, the non-graphenic carbon based material may be located on one of the two surfaces or on both. In some further embodiments, additional graphenic carbon may also present on the surface(s) of the single layer graphene.

The preferred embodiments may be further understood by the following non-limiting examples.

### EXAMPLE

### Perforated Graphene-Based Materials

FIGS. 1A and 1B are TEM images illustrating a portion of a sheet of graphene-based material after perforation using UV-oxygen treatment. FIG. 1B shows an enlarged portion of FIG. 1A. Label 10 indicates a region of graphene, the brighter surrounding areas include largely non-graphenic carbon and the dark regions are pores. The graphene based material was prepared by chemical vapor deposition then subjected to ion beaming while on the copper growth substrate with Xe ions at 500V at 80° C. with a fluence of 1.25×10¹³ ions/cm². Then the material was transferred to a TEM grid and then while suspended received 400 seconds of treatment at atmospheric pressure with atmospheric gas with Ultra-Violet (UV) parameters as described. The intensity was 28 mW/cm² at 6 mm.

FIGS. 2A and 2B are TEM images illustrating a portion of a sheet of graphene based material after perforation using Xe ions. FIG. 2B shows an enlarged portion of FIG. 2A. The graphene based material was prepared by chemical vapor deposition, pretreated, then transferred to a TEM grid and irradiated with Xe ions at 20 V and 2000 nAs. 2000 nAs=1.25×10¹⁵ ions/cm². The area % of pores was 5.8%.

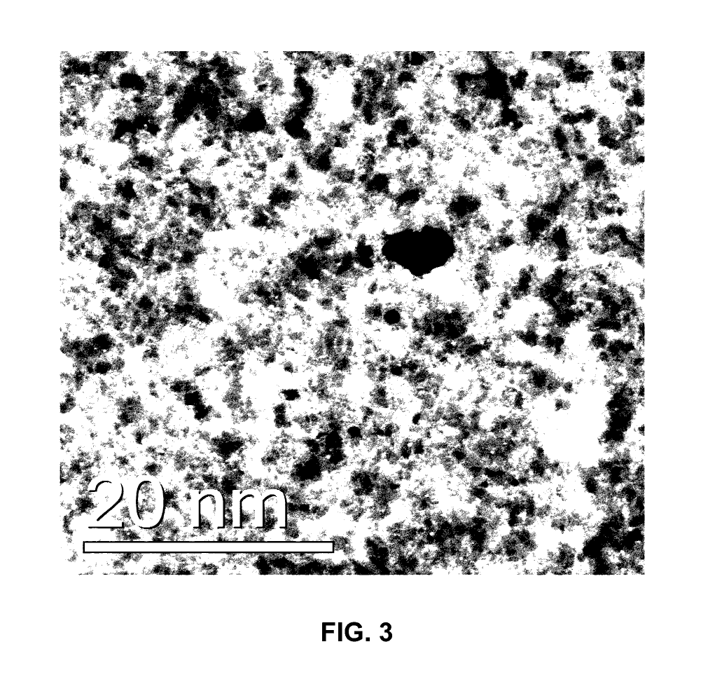

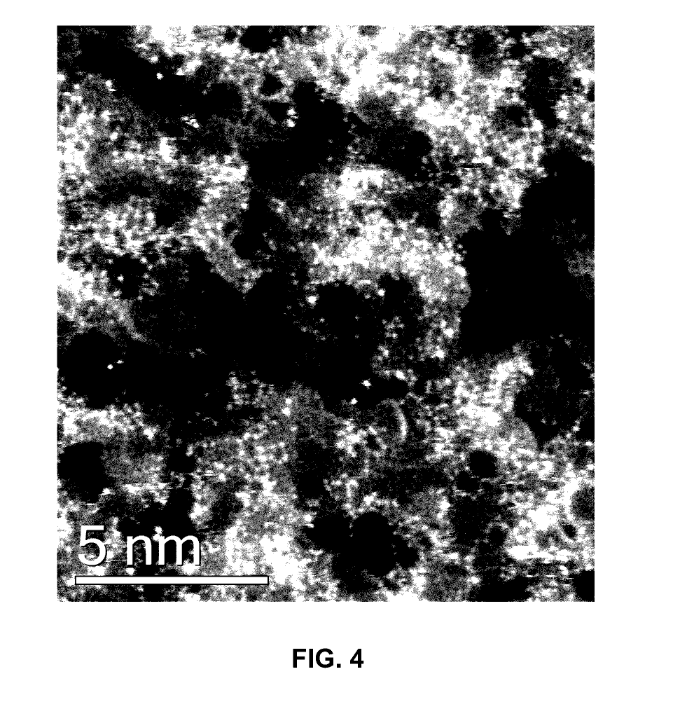

FIG. 3 and FIG. 4 are TEM images illustrating graphene based material after perforation using Ne ions. FIG. 4 is at higher magnification. The graphene based material was prepared by chemical vapor deposition, pretreated, then transferred to a TEM grid and irradiated with Ne ions at 23 kV with a fluence of 4×10¹⁷ ions/cm.

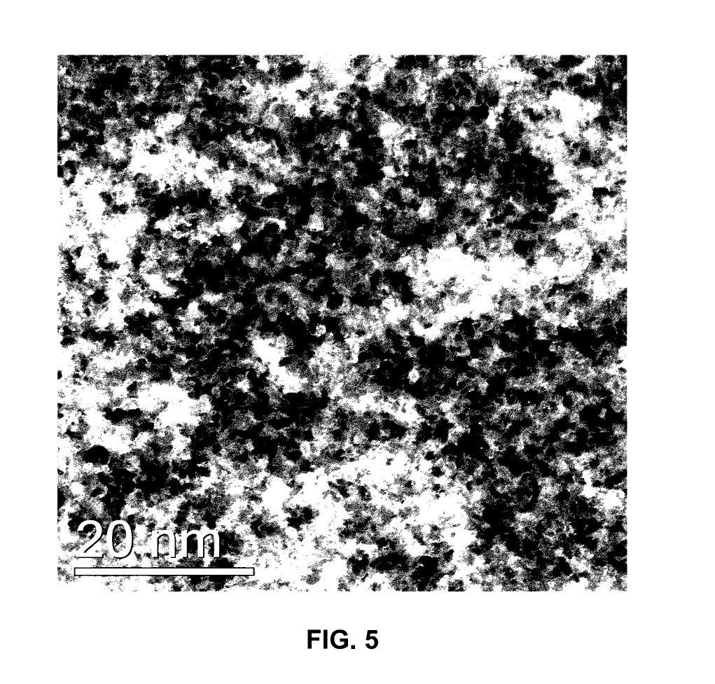

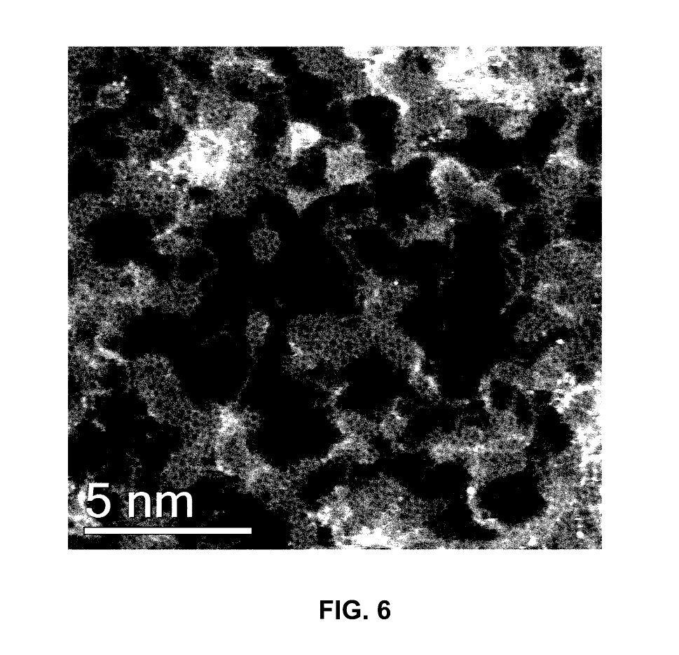

FIG. 5 and FIG. 6 are TEM images illustrating graphene based material after perforation using He ions. FIG. 6 is at higher magnification. The graphene based material was prepared by chemical vapor deposition, pretreated, then transferred to a TEM grid and irradiated with He ions at 25 kV with a fluence of 1×10²⁰ ions/cm².

The perforations generally appear as darker regions in these images.

Although the disclosure has been described with reference to the disclosed embodiments, one having ordinary skill in the art will readily appreciate that these are only illustrative of the disclosure. It should be understood that various modifications can be made without departing from the spirit of the disclosure. The disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that aspects of the disclosure may include only some of the described embodiments. Accordingly, the disclosure is not to be seen as limited by the foregoing description.

Every formulation or combination of components described or exemplified can be used to practice embodiments, unless otherwise stated. Specific names of compounds are intended to be exemplary, as it is known that one of ordinary skill in the art can name the same compounds differently. When a compound is described herein such that a particular isomer or enantiomer of the compound is not specified, for example, in a formula or in a chemical name, that description is intended to include each isomers and enantiomer of the compound described individual or in any combination. One of ordinary skill in the art will appreciate that methods, device elements, starting materials and synthetic methods other than those specifically exemplified can be employed in the practice of the embodiments without resort to undue experimentation. All known functional equivalents, of any such methods, device elements, starting materials and synthetic methods are intended to be included in the embodiments. Whenever a range is given in the specification, for example, a temperature range, a time range, or a composition range, all intermediate ranges and subranges, as well as all individual values included in the ranges given are intended to be included in the disclosure. When a Markush group or other grouping is used herein, all individual members of the group and all combinations and subcombinations possible of the group are intended to be individually included in the disclosure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The embodiments illustratively described herein suitably may be practiced in the absence of any element or elements, limitation or limitations which is not specifically disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the embodiments claimed. Thus, it should be understood that although some embodiments have been specifically disclosed by preferred features and optional features, modification and variation of the concepts herein disclosed may be resorted to by those skilled in the art, and that such modifications and variations are considered to be within the scope of the embodiments as identified by the appended claims.

In general the terms and phrases used herein have their art-recognized meaning, which can be found by reference to standard texts, journal references and contexts known to those skilled in the art. Any preceding definitions are provided to clarify their specific use in the context of the preferred embodiments.

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

All patents and publications mentioned in the specification are indicative of the levels of skill of those skilled in the art to which the preferred embodiments pertain. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claims.

1. A perforated sheet of graphene-based material having an area and comprising:
a perforated single layer of graphene;
a plurality of perforations in the single layer of graphene located over greater than 10% of the area of the single layer of graphene, the perforations having a mean pore size selected form the range of 0.3 nm to 1 μm;
wherein the perforations are characterized by a density of perforations selected from the range of 2/nm² to 1/μm²; and,
wherein the perforated area corresponds to 0.1% or greater of said area of said sheet of graphene-based material.

2. The perforated sheet of graphene-based material of claim 1, wherein the perforations are characterized by a distribution of pores with a dispersion characterized by a coefficient of variation of 0.1 to 2.

3. The perforated sheet of graphene-based material of claim 2, wherein said single layer graphene is characterized by an average size domain for long range order greater than or equal to 1 μm.

4. The perforated sheet of graphene-based material of claim 1, wherein said single layer graphene has an extent of disorder characterized long range lattice periodicity on the order of 1 micrometer.

5. The perforated sheet of graphene-based material of claim 1, wherein the perforated graphene-based material does not exhibit long range order.

6. The perforated sheet of graphene-based material of claim 1, wherein at least one lateral dimension of the single layer of graphene is from 10 nm to 10 cm.

7. The perforated sheet of graphene-based material of claim 6, wherein the single layer graphene comprises at least two surfaces and greater than 10% and less than 80% of said surfaces of said single layer graphene is covered by said non-graphenic carbon-based material.

8. The perforated sheet of graphene-based material of claim 7, wherein said non-graphenic carbon-based material is in physical contact with at least one of the surfaces of said single layer graphene.

9. A perforated sheet of graphene-based material comprising:
a perforated single layer graphene having a plurality of perforations characterized in that the perforations are located over greater than 10% of said area of said sheet of graphene-based material and the mean pore size of the perforations is selected from the range of 0.3 nm to 1 μm.

10. A perforated sheet of graphene-based material, the graphene-based material comprising:
a single layer graphene;
a plurality of perforations in the single layer graphene characterized in that the perforations are located over greater than 10% of said area of said sheet of graphene-based material and the mean pore size of the perforations is selected from the range of 0.3 nm to 1 μm.

11. The perforated sheet of graphene-based material of claim 10, wherein the perforations are characterized by a distribution of pores with a dispersion characterized by a coefficient of variation of 0.1 to 2.

12. The perforated sheet of graphene-based material of claim 9, wherein the coefficient of variation of the pore size is 0.5 to 2.

13. The perforated sheet of graphene-based material of claim 9, wherein the coefficient of variation of the pore size is 0.1 to 0.5.

14. The perforated sheet of graphene-based material of claim 11, wherein the perforations are characterized by a density of perforations selected from the range of 2/nm² to 1/μm².

15. The perforated sheet of graphene-based material of claim 14, wherein the perforated area corresponds to 0.1% or greater of said area of said sheet of graphene-based material.

16. The sheet of graphene-based material of claim 15 wherein the perforations are characterized by an average area of said perforations selected from the range of 0.2 nm² to 0.25 μm².

17. The perforated sheet of graphene-based material of claim 9, wherein said single layer graphene is characterized by an average size domain for long range order greater than or equal to 1 μm.

18. The perforated sheet of graphene-based material of claim 9 wherein said single layer graphene has an extent of disorder characterized long range lattice periodicity on the order of 1 micrometer.

19. The perforated sheet of graphene-based material of claim 9, wherein said single layer graphene has an extent of disorder characterized by less than 1% content of lattice defects.

20. The perforated sheet of graphene-based material of claim 9, wherein the crystal lattice of the single layer graphene is disrupted over the scale of 1 nm to 10 nm.

21. The perforated sheet of graphene-based material of claim 10, wherein the perforated graphene-based material does not exhibit long range order.

22. The perforated sheet of graphene-based material of claim 21, wherein the thickness of the sheet is from 0.3 nm to 10 nm.

23. The perforated sheet of graphene-based material of claim 22, wherein at least one lateral dimension of the sheet is from 10 nm to 10 cm.

24. The perforated sheet of graphene-based material of claim 9, further comprising a non-graphenic carbon-based material provided on said single layer graphene.

25. The perforated sheet of graphene-based material of claim 24, wherein the single layer graphene comprises at least two surfaces and greater than 10% and less than 80% of said surfaces of said single layer graphene is covered by said non-graphenic carbon-based material.

26. The perforated sheet of graphene-based material of claim 24, wherein said non-graphenic carbon-based material is in physical contact with at least one of the surfaces of said single layer graphene.

27. The perforated sheet of graphene-based material of claim 24, wherein said non-graphenic carbon-based material does not exhibit long range order.

28. The perforated sheet of graphene-based material of claim 24, wherein said non-graphenic carbon-based material has an elemental composition comprising carbon, hydrogen and oxygen.

29. The perforated sheet of graphene-based material of claim 24, wherein said non-graphenic carbon-based material has a molecular composition comprising amorphous carbon, one or more hydrocarbons, oxygen containing carbon compounds, nitrogen containing carbon compounds or any combination of these.

30. The perforated sheet of graphene-based material of claim 24, wherein said non-graphenic carbon-based material comprises 10% to 100% carbon.

31. The perforated sheet of graphene-based material of claim 24, wherein said non-graphenic carbon-based material further comprises non-carbon elements.

32. The perforated sheet of graphene-based material of claim 31, wherein said non-carbon elements are selected from the group consisting of hydrogen, oxygen, silicon, copper and iron.

33. The perforated sheet of graphene-based material of claim 31, wherein said non-graphenic carbon-based material is characterized by substantially limited mobility.

34. The perforated sheet of graphene-based material of claim 31, wherein said non-graphenic carbon-based material is substantially nonvolatile.

35. A method for perforating a sheet of graphene-based material, said method comprising:
positioning said sheet of graphene-based material comprising a single layer graphene having at least two surfaces; and a non-graphenic carbon-based material provided on said single layer graphene; wherein greater than 10% and less than 80% of said surfaces of said single layer graphene is covered by said non-graphenic carbon-based material; and
exposing the sheet of graphene-based material to ions characterized by an ion energy ranging from 10 eV to 100 keV and fluence ranging from 1×10¹³ ions/cm² to 1×10²¹ ions/cm².

36. The method of claim 35, wherein the ions are provided by an ion flood source.

37. The method of claim 35, wherein the ions are noble gas ions.

38. The method of claim 35, wherein the ions are selected from the group consisting of Xe⁺ ions, Ne⁺ ions, or Ar⁺ ions.

39. The method of claim 38, wherein the ion energy ranges from 5 keV to 50 keV and the ion dose ranges from 5×10¹⁴ ions/cm² to 5×10¹⁵ ions/cm².

40. The method of claim 38, wherein the sheet of graphene-based material is exposed to the ions in an environment comprising partial pressure of 5×10⁻⁴ torr to 5×10⁻⁵ torr of oxygen, nitrogen or carbon dioxide at a total pressure of 10⁻³ torr to 10⁻⁵ torr.

41. The method of claim 38, wherein the ion energy ranges from ion energy ranging from 100 eV to 1000 eV and the ion dose ranges from 1×10¹³ ions/cm² to 1×10¹⁴ ions/cm².

42. The method of claim 35, wherein the ions are helium ions.

43. The method of claim 42, wherein the ion energy ranges from ion energy ranging from 1 keV to 40 keV and the ion dose ranges from 1×10¹⁹ ions/cm² to 1×10²¹ ions/cm².

44. A method for perforating a sheet of graphene-based material, said method comprising:
positioning said sheet of graphene-based material comprising a single layer graphene having at least two surfaces; and a non-graphenic carbon-based material provided on said single layer graphene; wherein greater than 10% and less than 80% of said surfaces of said single layer graphene is covered by said non-graphenic carbon-based material; and
exposing said sheet of graphene-based material to ultraviolet radiation and an oxygen containing gas at an irradiation intensity from 10 to 100 mW/cm² at a distance of 6 mm for a time from 60 to 1200 sec.

45. The method of claim 44, wherein the oxygen containing gas is air at atmospheric pressure.
